(19) United States
(12) Patent Application Publication
(10) Pub. No.: US 2008/0121276 A1
(43) Pub. Date: May 29, 2008

(54) SELECTIVE ELECTROLESS DEPOSITION FOR SOLAR CELLS

(75) Inventors: Sergey Lopatin, Morgan Hill, CA (US); Arulkumar Shanmugasundram, Palo Alto, CA (US); Robert Z. Bachrach, Burlingame, CA (US); Charles Gay, Westlake Village, CA (US); David Eaglesham, Livermore, CA (US)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS, INC.

(21) Appl. No.: 11/564,812

(22) Filed: Nov. 29, 2006

(51) Int. Cl. H01L 31/00

(52) U.S. Cl. 136/256

(57) ABSTRACT

A metal contact structure of a solar cell substrate includes a contact with a conductive layer or a capping layer that is formed using an electroless plating process. The contact may be disposed within a hole formed through the solar cell substrate or on a non-light-receiving surface of the solar cell substrate. The electroless plating process for the conductive layer uses a seed layer that includes an activation layer for electroless plating.

### BACKGROUND OF THE INVENTION

1. Field of the Invention

Embodiments of the present invention generally relate to the fabrication of solar cells and particularly to the formation of certain layers of a solar cell by electroless deposition.

2. Description of the Related Art

Solar cells are photovoltaic devices that convert sunlight directly into electrical power. The most common solar cell material is silicon (Si), which is in the form of single or polycrystalline wafers. Gallium arsenide is another material used for solar cells, among others. Because the cost of electricity generated using silicon-based solar cells is higher than the cost of electricity generated by traditional methods, there has been an effort to reduce the cost of solar cells.

FIG. 1A schematically depicts a standard silicon solar cell 100 fabricated from a single crystal silicon wafer 110. The wafer 110 includes a p-type base region 101, an n-type emitter region 102, and a p-n junction region 103 disposed therebetween. Generally, an n-type region, or n-type semiconductor, is formed by doping the semiconductor with certain types of atoms in order to increase the number of negative charge carriers, i.e., electrons. For silicon, which has four valence electrons, the incorporation of atoms with five valence electrons into the crystal lattice in place of a Si atom, e.g., phosphorus (P), arsenic (As), or antimony (Sb), results in an atom with four covalent bonds and one unbonded electron. This extra electron is only weakly bound to the atom and can easily be excited into the conduction band. Similarly, a p-type region, or p-type semiconductor, is formed by the addition of trivalent atoms to the crystal lattice, resulting in a missing electron from one of the four covalent bonds normal for the silicon lattice. Thus the dopant atom can accept an electron from a neighboring atoms' covalent bond to complete the fourth bond. The dopant atom accepts an electron, causing the loss of half of one bond from the neighboring atom and resulting in the formation of a “hole.”

When light falls on the solar cell, energy from the incident photons generates electron-hole pairs on both sides of the p-n junction region 103. Electrons diffuse across the p-n junction to a lower energy level and holes diffuse in the opposite direction, creating a negative charge on the emitter and a corresponding positive charge build-up in the base. When an electrical circuit is made between the emitter and the base, a current will flow. The electrical current generated by the semiconductor when illuminated flows through contacts disposed on the frontside 120, i.e. the light-receiving side, and the backside. The top contact structure is generally configured as widely-spaced thin metal strips, or fingers 104, that supply current to a larger bus bar 105. The back contact 106 is generally not configured as multiple thin strips since it does not prevent incident light from striking solar cell 100. Solar cell 100 is generally covered with a thin layer of dielectric material, such as Si₃N₄, to act as an anti-reflection coating, or ARC, to minimize light reflection from the top surface of silicon wafer 100.

Another type of solar cell design, referred to as a pin-up module or PUM cell, has been developed for simplified assembly and higher efficiency. FIG. 1B is a plan view of the top contact structure of one example of a PUM cell. In this design, a plurality of holes is formed through the solar cell substrate and the holes serve as vias for interconnection of the top contact structure to a backside conductor by using pins. One advantage of the PUM concept is the elimination of the busbars, such as bus bar 105 illustrated in FIG. 1A, from the light-receiving side of the substrate, thereby increasing efficiency of the cell. Another is that resistive losses are reduced because current produced by the solar cell is collected at holes equally spaced over the substrate. Further, resistive losses will not increase with cell area and, hence, larger solar cells may be manufactured without a loss in efficiency.

FIG. 1D is a partial schematic cross section of one example of a PUM cell 130 showing a contact 134. Similar to a standard solar cell, such as solar cell 100, PUM cell 130 includes a single crystal silicon wafer 110 with a p-type base region 101, an n-type emitter region 102, and a p-n junction region 103 disposed therebetween. PUM cell 130 also includes a plurality of through-holes 131, which are formed between the light-receiving surface 132 and the backside 133 of PUM cell 130. The through-holes 131 allow the formation of contact 134 between the light-receiving surface 132 and the backside 133. Disposed in each through-hole 131 is a contact 134, which includes a top contact structure 135 disposed on light-receiving surface 132, a backside contact 136 disposed on backside 133, and an interconnect 137, which fills through-hole 131 and electrically couples top contact structure 135 and backside contact 136. An anti-reflective coating 107 may also be formed on light receiving surface 132 to minimize reflection of light energy therefrom.

The surfaces of contact 134 that are in contact with wafer 110 are adapted to form an ohmic connection with n-type emitter region 102. An ohmic contact is a region on a semiconductor device that has been prepared so that the current-voltage (I-V) curve of the device is linear and symmetric, i.e., there is no high resistance interface between the doped silicon region of the semiconductor device and the metal contact. Low-resistance, stable contacts are critical for the performance and reliability of integrated circuits, and their preparation and characterization are major efforts in circuit fabrication. Hence, after contact 134 has been formed in through-hole 131, on light-receiving surface 132, and on backside 133, an annealing process of suitable temperature and duration is typically performed in order to produce the necessary low resistance metal silicide at the contact/semiconductor interface. A backside contact 139 completes the electrical circuit required for PUM cell 130 to produce a current by forming an ohmic contact with p-type base region 101 of wafer 110.

Top contact structure 135 is configured to act as one or more of the fingers of a conventional solar cell, such as fingers 104 of solar cell 100 depicted in FIG. 1A. Wider conductors on light-receiving surface 132 reduce resistance losses but increase shadowing losses by covering more of light-receiving surface 132. Therefore, maximizing cell efficiency requires balancing these opposing design constraints.

Referring back to FIG. 1D, the finger width and geometry of the PUM cell have been optimized to maximize cell efficiency for the cell. In this configuration, illustrated in FIG. 1C, a top contact structure for a PUM cell is configured as a grid electrode 138, which consists of a plurality of various width finger segments 135A. The width of a particular finger segment 135A is selected as a function of the current to be carried by that finger segment 135A. In addition, finger segments 135A are configured to branch as necessary to maintain finger spacing as a function of finger width. This minimizes resistance losses as well as shadowing by finger segments 135A.

Grid electrode contacts for PUM cells have been fabricated using a screen printing process in which a silver-containing paste is formed into the desired pattern on a substrate surface, pressed into through-holes in the substrate surface, and subsequently annealed. However, there are several issues with this manufacturing method. First, the thin fingers of the grid electrode, when formed by the screen printing process, can be formed with breaks. Second, porosity present in the grid electrode and contact results in greater resistive losses. Third, electrical shunts may be formed by diffusion of silver from the contact into the p-type base region or on the surface of the substrate backside. Shunts on the substrate backside are caused by poor definition of backside contacts such as waviness, and/or silver residue. Lastly, silver-based paste is a relatively expensive material for forming conductive components of a solar cell.

Another approach to forming very thin, robust fingers on surfaces of a solar cell substrate involves cutting grooves in surfaces of the substrate with a laser. The grooves are subsequently filled by an electroless plating method. However the laser-cut grooves are a source of macro- and micro-defects. The laser-cut edge is not well-defined, causing waviness on the finger edges, and the heat of the laser introduces defects into the silicon.

### SUMMARY OF THE INVENTION

The present invention provides a contact structure for solar cells having low resistivity and clearly defined features. The present invention further provides a method of forming a contact structure for solar cells with low resistivity and clearly defined features that does not damage the solar cell substrate.

According to embodiments of the present invention, a metal contact structure of a solar cell substrate includes a contact with a conductive layer or a capping layer that is formed using an electroless plating process. The contact may be disposed within a hole formed through the solar cell substrate or on a non-light-receiving surface of the solar cell substrate. The electroless plating process for the conductive layer uses a seed layer that includes an activation layer for electroless plating.

In one embodiment, a metal contact structure for a solar cell comprises a solar cell substrate having a base region and an emitter region and a contact disposed adjacent to the emitter region, wherein the contact structure has a bulk conductive layer and a capping layer that covers the bulk conductive layer. The metal contact structure may be disposed within a hole that is formed through the substrate. The contact may further comprise a seed layer disposed between the bulk conductive layer and the emitter region. The seed layer and the capping layer may be electrolessly deposited.

In another embodiment, a metal contact structure for a solar cell comprises a solar cell substrate having a base region and an emitter region and a contact disposed adjacent to the emitter region, wherein the contact has a bulk conductive layer and an electrolessly deposited seed layer disposed between the bulk conductive layer and the emitter region. The contact may further comprise an electrolessly deposited capping layer that covers the bulk conductive layer.

According to one embodiment, a method for forming a contact on a solar cell substrate comprises forming a contact having a bulk conductive layer adjacent an emitter region of the substrate and forming a capping layer on the bulk conductive layer through an electroless plating process. The bulk conductive layer may be formed on the activation layer through an electroless plating process. The method may further comprise forming a seed layer adjacent the emitter region through a PVD process and forming an activation layer on the seed layer. Alternatively, the method may further comprise forming an ohmic contact layer adjacent the emitter region.

According to another embodiment, a method for forming a contact on a solar cell substrate comprises forming an activation layer for electroless deposition on a solar cell substrate and forming a bulk conductive layer for the contact on the activation layer. The method may further comprise forming a capping layer by an electroless process to cover the bulk conductive layer. The activation layer may be formed on the sidewalls of a through-hole in the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A schematically depicts a standard silicon solar cell fabricated from a single crystal silicon wafer.

FIG. 1B is a partial schematic cross section of a top contact structure for one example of a solar cell.

FIG. 1C illustrates a top contact structure for a PUM cell.

FIG. 1D is a partial schematic cross section of one example of a PUM cell showing a contact.

FIGS. 2A-C are schematic side views of an exemplary electroless deposition system capable of performing an activation or electroless plating process on all surfaces of a substrate.

FIG. 3A illustrates a partial schematic cross section of a solar cell according to a first embodiment of the invention.

FIG. 3B illustrates a partial schematic cross section of a solar cell according to a second embodiment of the invention.

FIG. 3C illustrates a partial schematic cross section of a solar cell according to a third embodiment of the invention.

FIGS. 3D, 3E and 3F illustrate an enlarged view of the region of a contact indicated in FIG. 3A.

FIG. 4A is a flow chart summarizing a process sequence for depositing a conductive layer onto a silicon substrate to form an improved contact for a solar cell.

FIG. 4B is a flow chart summarizing a process sequence for selectively depositing a seed and/or bulk conductive layer via electroless deposition onto a previously formed metal-containing layer of a solar cell structure.

FIG. 5A is a flow chart summarizing a process sequence for forming a contact structure for a solar cell.

FIG. 5B is a flow chart summarizing a process sequence for forming a contact structure for a solar cell with an electroless seed layer.

FIG. 5C is a flow chart summarizing a process sequence for forming a contact structure using sequential electroless deposition steps.

FIGS. 6A-6F are partial schematic side views of a solar cell contact being formed by the process sequence outlined in FIG. 5A.

For clarity, identical reference numerals have been used, where applicable, to designate identical elements that are common between figures. It is contemplated that features of one embodiment may be incorporated in other embodiments without further recitation.

### DETAILED DESCRIPTION

Embodiments of the invention contemplate improved metal contact structures for solar cells through the use of electroless plating onto a solar cell substrate. Solar cell substrates that may benefit from the invention include substrates composed of single crystal silicon (Si), poly-crystal silicon, muliti-crystal silicon, germanium (Ge), and gallium arsenide (GaAs), as well as heterojunction cells, such as GaInP/GaAs/Ge or ZnSe/GaAs/Ge substrates.

Substrate processing systems capable of performing electroless deposition are known in the art, and in operation may be used to perform an electroless activation process, an electroless plating process, and a post clean process on a surface of a substrate. In some configurations, an electroless deposition system capable of performing aspects of the invention may include more than one processing station, for example an activation station and a deposition station, which is known as an electroless twin processing station. An electroless twin configuration may better enable the electroless deposition process. An electroless twin configuration may further include a substrate transfer shuttle that is positioned between the two processing stations and is configured to transfer substrates therebetween.

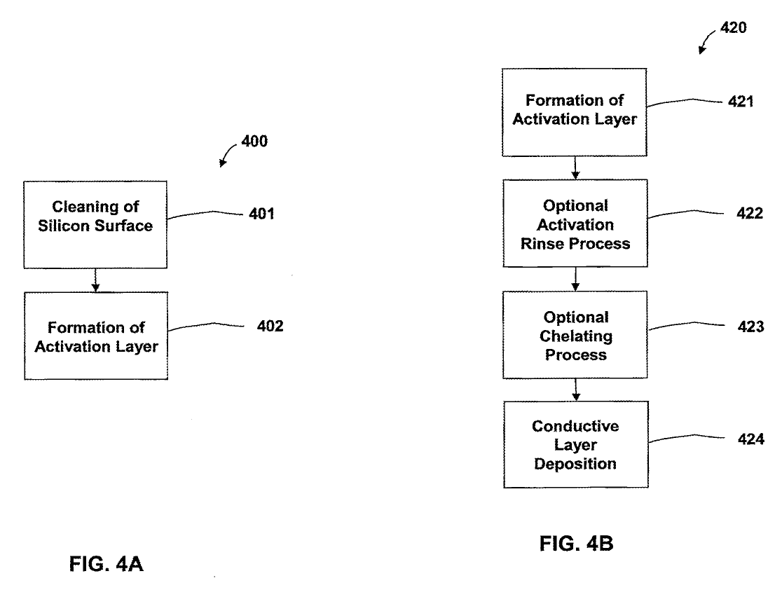

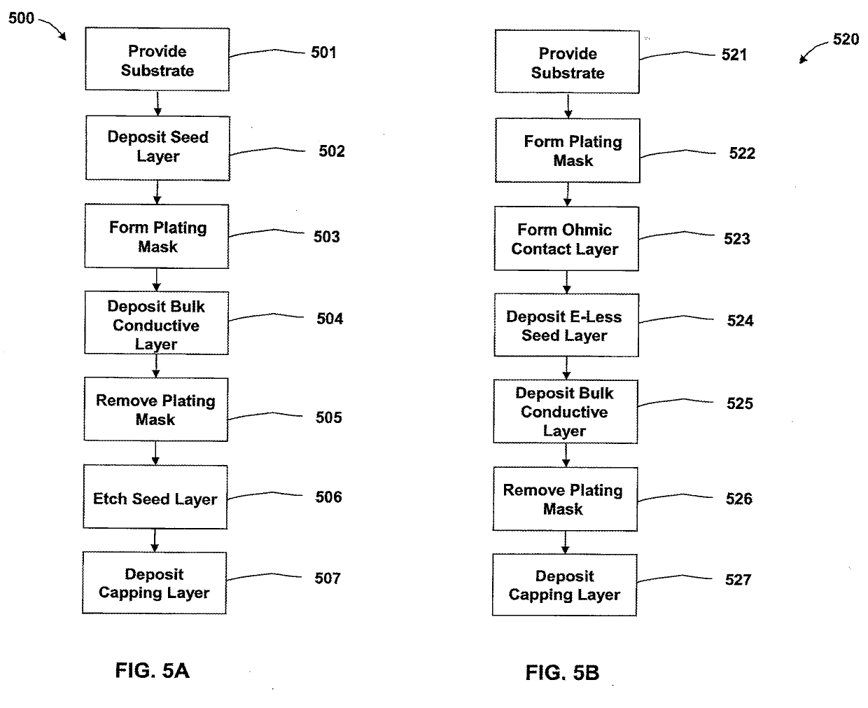

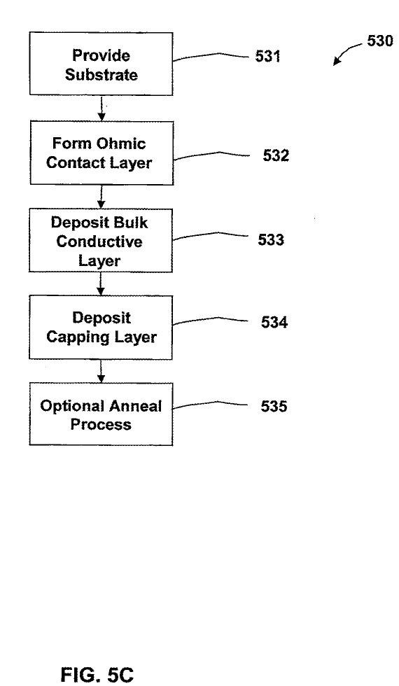

Typical electroless processing stations include a rotatable substrate support assembly that is configured to support a solar cell substrate for processing in a face-up orientation, i.e., the frontside, or light-receiving side, of the substrate is facing away from the support assembly. Typical electroless processing stations also include a fluid dispensing arm that is configured to pivot over the substrate during processing to dispense a processing fluid onto the front side of the substrate. Because the dispensing arm may include more than one fluid conduit therein, an electroless processing station may perform multiple processes on a solar cell substrate, for example electroless deposition and post deposition clean. A more detailed description of an exemplary electroless deposition system that may perform embodiments of the invention on a surface of a substrate may be found in commonly assigned U.S. patent application Ser. No. 10/996,342, filed Jul. 28, 2005, which is hereby incorporated by reference in its entirety to the extent not inconsistent with the present invention. Other configurations of face-up electroless deposition stations may include conveyor-type stations, in which substrates are moved continuously through an electroless deposition bath. Electroless deposition processes related to embodiments of the invention are described below in conjunction with FIGS. 4A, 4B, 5A, 5B, and 5C.

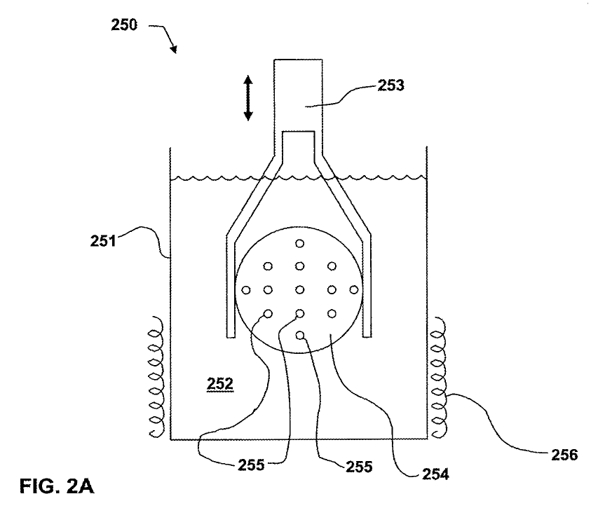

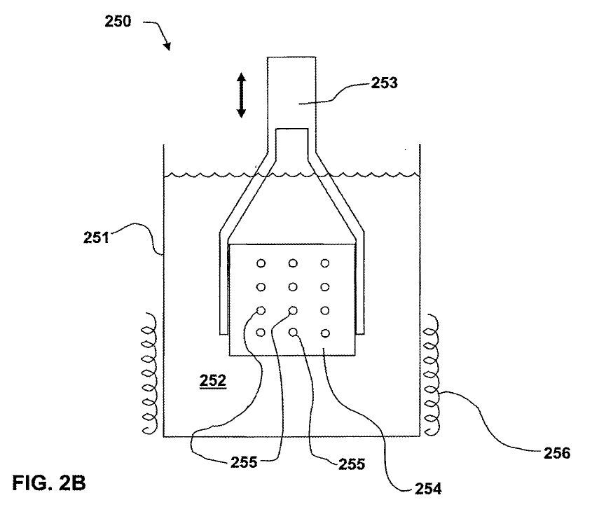

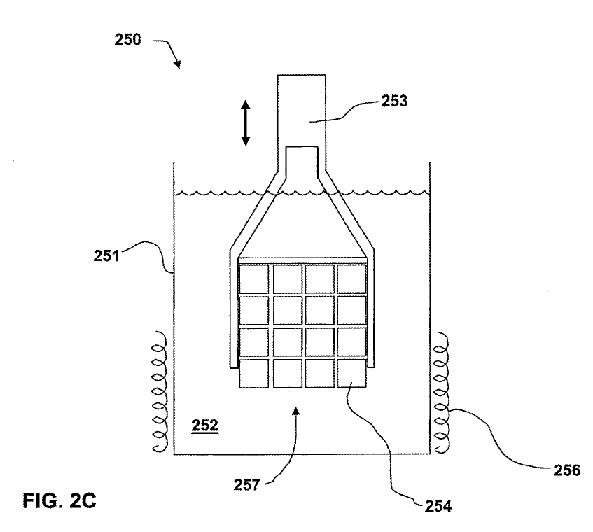

FIG. 2A is a schematic side view of an exemplary electroless deposition system 250 capable of performing an activation or electroless plating process on all surfaces of a substantially circular substrate. FIG. 2B illustrates electroless deposition system 250 configured for processing a substantially square substrate. In either case, system 250 may be useful for substrates requiring electroless deposition on the frontside and backside, and/or inside of through-holes. Electroless deposition system 250 includes a tank 251, which is adapted to contain a solution 252, which may be an activation solution or an electroless plating solution. A gripper 253 or other substrate-handling device may transfer a substrate 254 into the tank 251 for immersion into solution 252. The substrate 254 may have a plurality of through-holes 255 disposed there-through. Temperature control of solution 252 may be accomplished with heating elements 256. In one configuration, system 250 may be configured to accommodate batches of multiple substrates, wherein batch size may be as large as 25 to 1000 substrates. For example, gripper 253 may be adapted to transfer a batch cassette of multiple substrates into and out of tank 251. In this example, substrates may be processing in the batch cassette vertically. In another configuration, system 250 may include a conveyor system for continuous substrate movement through tank 251. In each of the above configurations, substrates may be oriented vertically (as shown) or horizontally. FIG. 2C illustrates another possible configuration of electroless deposition system 250, wherein an array 257 of multiple substrates 254 is processed in tank 251.

Aspects of the invention also contemplate the use of electrochemical plating (ECP) of low resistance materials, such as copper (Cu), onto surfaces of solar cells to produce contacts. ECP plating processes require the formation of a seed layer prior to electrochemical plating. In seed layer formation, a continuous seed layer is first formed over the surface features of the substrate via one of several methods, including physical vapor deposition (PVD), chemical vapor deposition (CVD,) or atomic layer deposition (ALD) processes. PVD, CVD, and ALD processes are known in the art and are used for the deposition of seed layers for subsequent ECP deposition. A seed layer may also be formed directly on a silicon surface by electroless plating methods, which are described below in conjunction with FIGS. 4A and 4B. After the formation of a seed layer on a substrate, the ECP process may be performed. In an ECP process, the surface features of a substrate are exposed to an electrolyte solution while an electrical bias is applied between the seed layer and an anode positioned within the electrolyte solution. For copper ECP, the anode may be composed of copper or copper-phosphorus alloy. Alternatively, anode may be an inert material and composed of platinized titanium. The electrolyte solution contains ions to be plated onto the surface of the substrate and the application of a cathodic type electrical bias thereto causes these ions in the electrolyte solution to be plated onto the seed layer. An exemplary ECP cell and method is described in commonly assigned U.S. patent application Ser. No. 10/627,336, filed Jul. 15, 2004, which is hereby incorporated by reference in its entirety to the extent not inconsistent with the present invention.

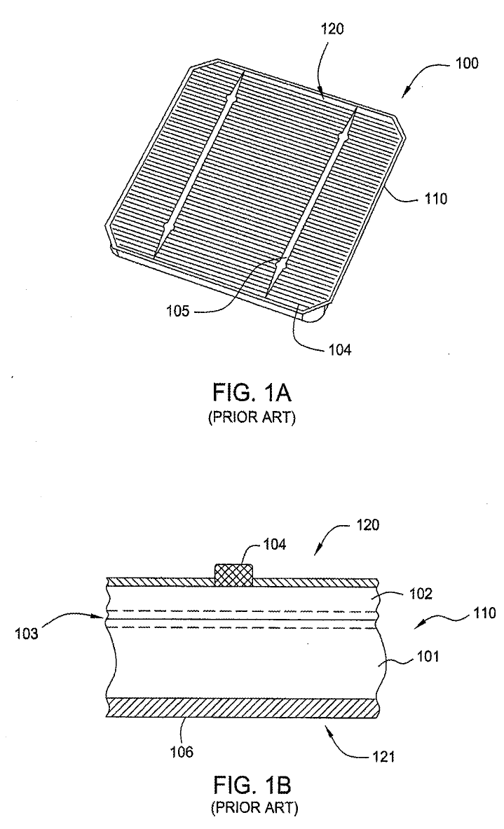

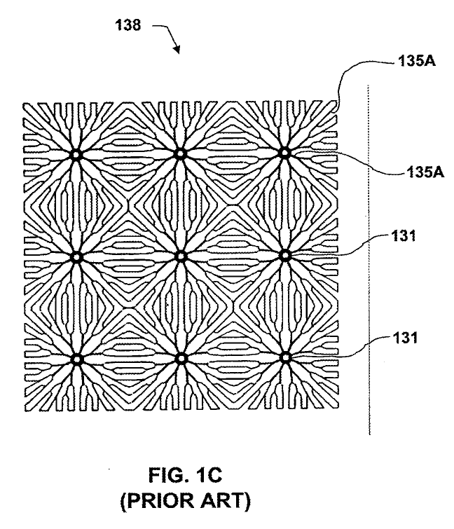

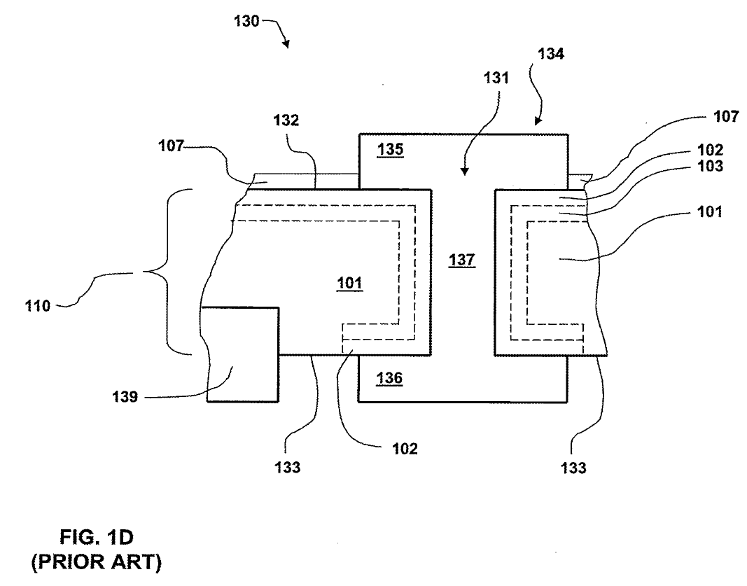

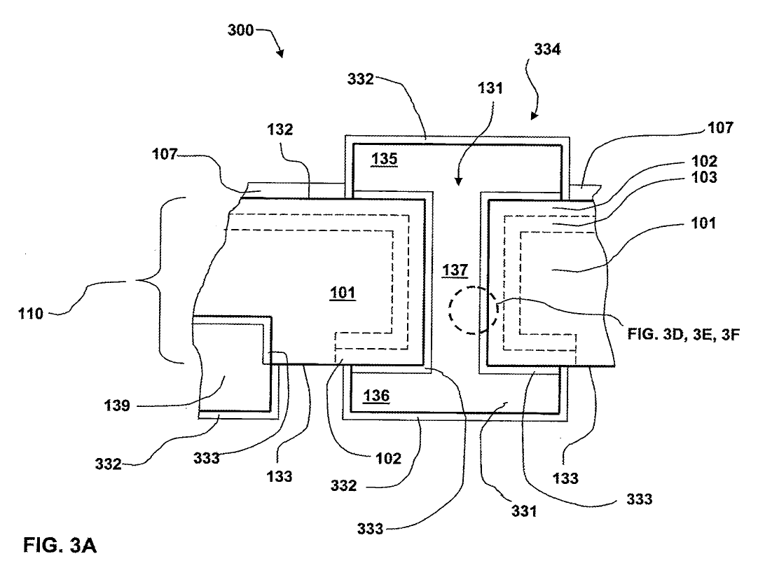

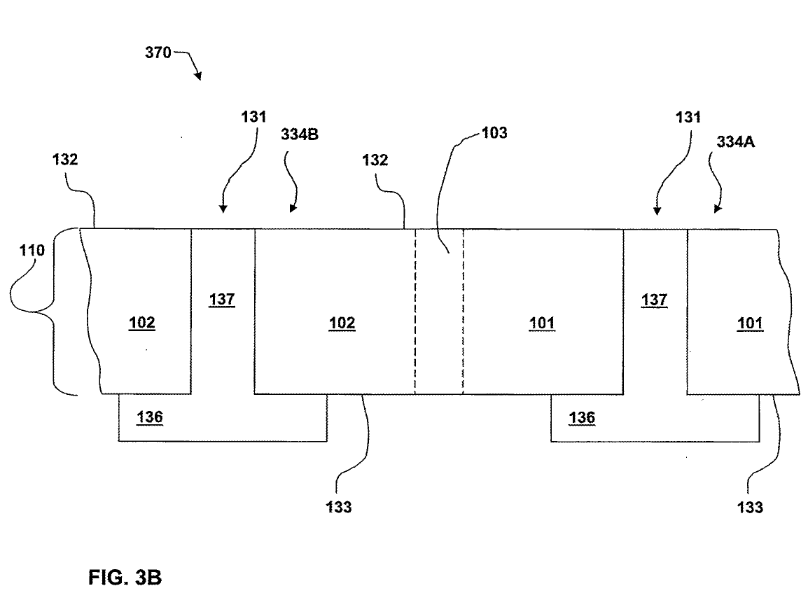

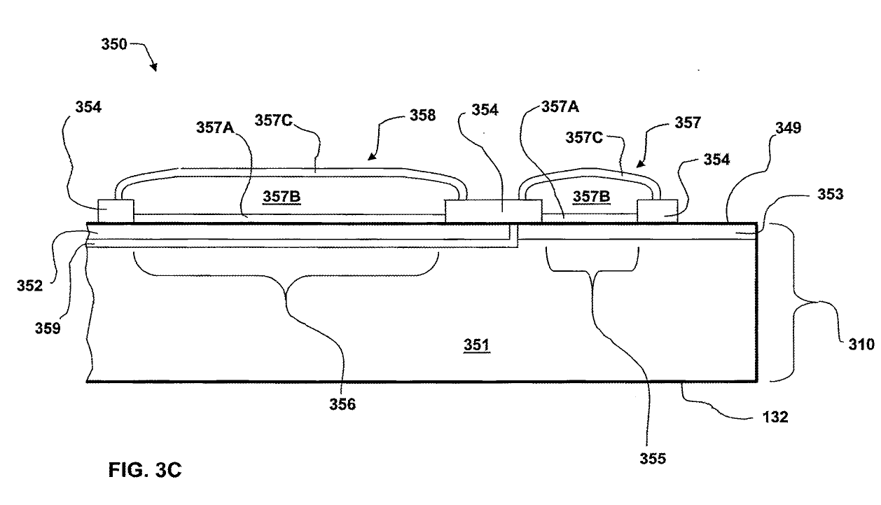

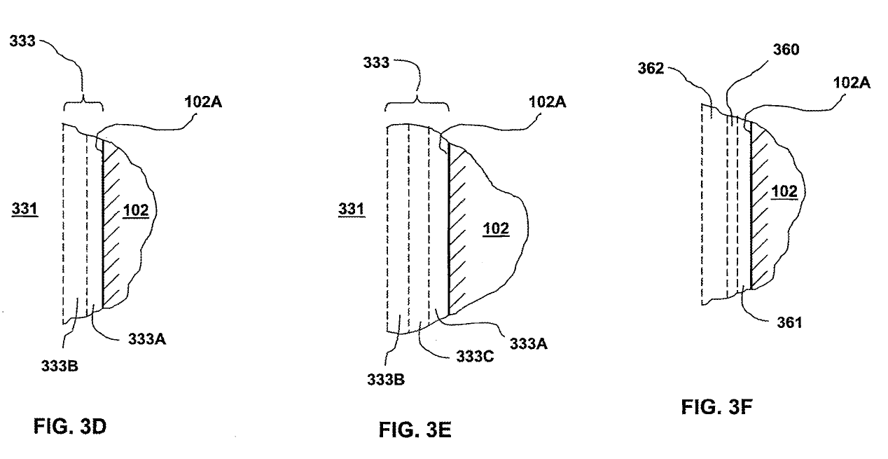

FIG. 3A illustrates a partial schematic cross section of a solar cell according to a first embodiment of the invention. The portion of the solar cell shown in FIG. 3A is a contact structure 300. Contact structure 300 is similar to that of PUM cell 130 described above in conjunction with FIG. 1B and identical numbers are used to depict common elements. Contact structure 300 is formed on a wafer 110 that consists of a material suitable for use as a substrate in a solar cell, such as silicon (Si), germanium (Ge), and gallium arsenide (GaAs), among others. Contact structure 300 includes a p-type base region 101, an n-type emitter region 102, and a p-n junction region 103 disposed therebetween. In other examples of solar cells, the n-type region and the p-type region may be transposed, i.e., the p-type region may serve as the emitter and the n-type region may serve as the base. For clarity, however, solar cells following the standard convention of a p-type base region and an n-type emitter region are used to describe aspects of the invention. A through-hole 131 is formed between the light-receiving surface 132 and the backside 133 of wafer 110, and a contact 334 is disposed in the through-hole. Contact 334 includes bulk conductive layer 331, which makes up the majority of contact 334, and a capping layer 332, which is disposed on the surfaces of contact 334 that are not in contact with wafer 110.

Contact structure 300 further includes a backside contact 139, an interconnect 137, a top contact structure 135, and a backside contact 136, which are described above in conjunction with FIG. 1B. Backside contact 139 may be substantially similar in make-up to contact 334. For example, backside contact 139 may also include a bulk conductive layer 331, a seed layer 333, and/or a capping layer 332. For clarity, bulk conductive layer 331, a seed layer 333, and capping layer 332 are described in detail below as components of contact 334.

Bulk conductive layer 331 consists of a low-resistivity, low-porosity conductive material that can be deposited via electrochemical plating and/or electroless plating, such as copper, silver (Ag), and combinations thereof. In one embodiment, bulk conductive layer 331 is an ECP-deposited copper layer, in which case contact 334 also includes a seed layer 333. Seed layer 333 may be an electroless metal seed layer (as shown in FIGS. 3D and 3E), or a PVD-deposited seed layer that has been enhanced by electroless metal deposition prior to electrochemical plating of the bulk conductive layer (as shown in FIG. 3F).

Capping layer 332 is a protective metallic layer that is deposited on surfaces of bulk conductive layer 331 by a selective electroless deposition process. Selective electroless deposition, i.e., deposition of a metallic layer only on selected surfaces of a substrate, takes place when a substrate having metallic and non-metallic surfaces is exposed to an electroless deposition solution. Electroless deposition only takes place on the metallic surfaces, leaving the non-metallic surfaces free of deposition. Capping layer 332 is used to minimize oxidation of contact surfaces of bulk conductive layer 331, particularly those adjacent the backside surface 133 of wafer 110, and therefore consists of a metallic material that is not susceptible to substantial oxidation and corrosion, such as tin (Sn), cobalt (Co), and/or nickel (Ni). Less oxidation or corrosion on the surface of bulk conductive layer 331 reduces the resistance of soldered connections thereto, improving cell efficiency. In addition, because soldered contacts are used to electrically connect contact 334 to an electrical circuit, capping layer 332 may also contain metals that provide more robust connections when soldered, such as tin (Sn).

There are a number of benefits associated with the structure of FIG. 3A when used as a contact structure for a solar cell. First, the edges of contacts are more sharply defined than with a screen printing or laser cutting process. Second, an anneal step is not required to form an ohmic contact between the silicon substrate and the contact, therefore there is no danger of shunts caused by diffusion of copper or other harmful metallic ions into the doped silicon region. Also, without an anneal step, there is less danger of stress-related breakage of the contact's delicate fingers. Third, a more robust soldering connection is formed; there is less oxidation of the bulk contact material, such as copper, meaning less resistive losses, and the inclusion of a tin-based alloy in the capping layer makes a high quality soldering connection possible.

FIG. 3B illustrates a partial schematic cross section of a solar cell according to a second embodiment of the invention. The portion of the solar cell shown in FIG. 3B is a contact structure 370. Contact structure 370 includes two through-holes 131 through wafer 110. One through-hole 131 is in a p-type base region 101, another through-hole 131 is in an n-type emitter region 102, and a p-n junction region 103 is disposed therebetween. A contact 334A fills the through-hole 131 in p-type base region 101 and a contact 334B fills the through-hole 131 in n-type emitter region 102. In addition, contacts 334A, 334B may not be disposed on light-receiving surface 132, thereby eliminating any shadowing effect on light-receiving surface 132. Contacts 334A, 334B are otherwise similar in make-up to the various configurations of contact 334 described above in conjunction with FIG. 3A. In this aspect, a solar cell may include a plurality of contacts that each form an ohmic contact with an equal number of respective a p-type base regions. Similarly, the solar cell may further include a plurality of contacts that each form an ohmic contact with an equal number of respective a n-type emitter regions. A bus or other conductive structure (not shown) may electrically connect all of the p-type base region contacts, and a second bus or conductive structure (not shown) may electrically connect all of the n-type emitter region contacts, thereby completing the electrical circuit necessary for the generation of electrical power by the solar cell.

The structure illustrated in FIG. 3B may allow the formation of a photovoltaic (PV) cell device with a plurality of mini-cells having reduced carrier recombination and increased current collection by metallic contacts. This can result in higher efficiency of the PV cell device.

FIG. 3C illustrates a partial schematic cross section of a solar cell according to a third embodiment of the invention. The portion of the solar cell shown in FIG. 3C is a backside contact structure 350. In this embodiment, the light-receiving surface 132 of a solar cell substrate 310 (shown at the bottom) may be contact-free, i.e. there is no shadowing of the substrate's light-receiving surface by contacts disposed on the frontside of the substrate. All contacts and metallization buses are made on the backside surface 349 of solar cell substrate 310. Contact structure 350 is formed on a wafer 310 that consist of a material suitable for use as a substrate in a solar cell, such as silicon (Si), germanium (Ge), and gallium arsenide (GaAs), among others. Contact structure 350 may include a bulk substrate region 351, which is a lightly-doped n-type region, a heavily doped n-type region 353, a heavily doped p-type region 352, and a junction region 359. A dielectric coating 354, such as Si₃N₄ or SiO₂, electrically isolates an emitter contact 357 from a base contact 358, and otherwise covers a minimal portion of backside surface 349. Areas of backside surface 349 that are not covered by dielectric coating 354 define apertures 355, 356, and are located over n-type region 353 and p-type region 352, respectively. Apertures 355, 356 in dielectric coating 354 may be formed on wafer 310 by conventional deposition and patterning techniques known in the art of integrated circuit fabrication. Alternatively, dielectric coating 354 may be deposited on selective regions of backside surface 349 by conventional deposition and patterning techniques known in the art of integrated circuit fabrication in order to form apertures 355, 356. Emitter contact 357 fills aperture 355 and base contact 358 fills aperture 356. A plurality of emitter contacts 357 may be formed on backside surface 349 and may be electrically coupled by one or more conductive buses (not shown). The electrical coupling may be performed by soldering of the conductive buses to the surface of each emitter contact 357. Similarly, a plurality of base contacts 358 may also be formed on backside surface 349 as necessary and may be electrically coupled by one or more conductive buses (not shown) via soldering connections.

Emitter contact 357 and base contact 358 each contain an ohmic contact layer 357A, which is in direct contact with n-type region 353 and p-type region 352 respectively, a bulk conductive layer 357B covering the ohmic contact layer 357A, and a capping layer 357C covering the bulk conductive layer 357B. In one aspect, one or more base contacts 358 cover the majority of backside surface 349, thereby collecting current with less resistance for a higher efficiency cell. In another aspect, emitter contact 357 may be disposed on the light-receiving surface of solar cell substrate 310 in the form of very narrow metal lines while base contact 358 is disposed on backside surface 349 in the form of very wide and thick conductive layers.

Ohmic contact layer 357A is an electrolessly deposited conductive layer deposited onto the surfaces of n-type region 353 and p-type region 352 that are exposed by apertures 355, 356. Ohmic contact layer 357A is a thin layer of conductive material relative to bulk conductive layer 357B. The function of ohmic contact layer 357A is to act as the ohmic contact between the metal contact 357 and the doped semiconductor, such as p-type region 352 or n-type region 353. In one aspect, ohmic contact layer 357A may include a diffusion barrier, such as a layer containing titanium (Ti), cobalt (Co), nickel (Ni), tungsten (W), molybdenum (Mo), and/or tantalum (Ta), to prevent the diffusion of harmful metal ions into p-type region 352 or n-type region 353. In this aspect, the diffusion barrier is deposited by a selective electroless process onto ohmic contact layer 357A.

Bulk conductive layer 357B is an electrolessly deposited conductor configured to carry the majority of the current produced by the cell. Bulk conductive layer 357B consists of low-resistance conductive material that can be deposited by a selective electroless process, such as copper (Cu), silver (Ag), and combinations thereof.

Capping layer 357C is a thin, electrolessly deposited conductive layer and is generally similar in composition and application to capping layer 331 described above in conjunction with FIG. 3A. That is, capping layer 357C is configured to protect bulk conductive layer 357B from unwanted oxidation as well as to provide a robust surface for solder connections to contact 357.

Benefits associated with the structure of FIG. 3C when used as a contact structure for a solar cell are generally the same as those described above for the contact structure depicted in FIG. 3A. In addition, by using deposition and patterning techniques known in the art of integrated circuit fabrication, very fine grid electrode structures may be produced on a solar cell.

As noted above, embodiments of the invention include the electroless deposition of metallic layers on various surfaces, including an ohmic contact layer on a silicon substrate, a barrier layer on an ohmic contact layer, a conductive layer on an previously formed metallic layer, and the deposition of a capping layer on a bulk conductive layer. Methods and chemistries for each scenario are described below.

FIG. 3D illustrates an enlarged view of the region of contact 334 indicated in FIG. 3A, wherein seed layer 333 is an electroless metal layer deposited directly onto a surface 102A of n-type emitter region 102. In this aspect, seed layer 333 includes an activation layer 333A and a conductive layer 333B.

Alternatively, an optional barrier layer 333C may be deposited between n-type emitter region 102 and bulk conductive layer 331. This is shown in FIG. 3E. Barrier layer 333C may be included in the structure of contact 334 to prevent the diffusion of harmful metallic ions into n-type emitter region 102 from contact 334. In one aspect, a thin layer of cobalt-containing material may be deposited over a metal silicide layer to act as a barrier layer. Activation layer 333A is an electroless metal layer deposited directly onto a surface 102A of n-type emitter region 102 and acts an ohmic contact layer for the solar cell. Formation of an ohmic contact layer is described below in conjunction with FIG. 4A. Conductive layer 333B may be an electroless metal layer and may act as a thin, conformal seed layer when bulk conductive layer 331 is to be subsequently deposited by an electroplating process. Alternatively, when bulk conductive layer 331 is formed by an electroless deposition process, conductive layer 333B may make up the majority of bulk conductive layer 331. In either case, conductive layer 333B is formed by the electroless deposition process described below in conjunction with FIG. 4B. Barrier layer 333C is an electrolessly deposited metal-containing layer that is formed on activation layer 333A. Methods for the formation of an electroless barrier layer are described below.

As another alternative, bulk conductive layer 331 may be an electrolessly deposited conductive layer, in which case a seed layer 333 is not required. However, electrolessly depositing barrier layer 333C on n-type emitter region 102 may still be advantageous.

FIG. 3F illustrates an alternative layer structure to the seed layer 333 shown in FIGS. 3D and 3E. This alternative layer structure includes an existing metal-containing layer 361 on the surface of a solar cell structure, an activation layer 360 formed on metal-containing layer 361, and a conductive layer 362 formed on activation layer 360. Metal-containing layer 361 may be an ohmic contact layer on the surface of a solar cell structure or metal-containing layer 361 may be a PVD, CVD, or ALD-deposited seed layer. Activation layer 360 is a mono-layer thickness initiation layer formed on metal-containing layer 361 by displacement plating of a catalytic metal such a palladium (Pd), platinum (Pt), ruthenium (Ru), osmium (Os), rhodium (Rh), or iridium (Ir). Displacement plating is the replacement or sacrifice of existing atoms on the upper surface of a material, e.g., metal-containing layer 361, by a secondary element, (e.g., palladium, platinum, ruthenium, etc.). Conductive layer 362 may be a seed layer for subsequent electroplating of a bulk conductive layer. Alternatively, conductive layer 362 may serve as the bulk conductive layer of the solar cell contact structure.

### Electroless Deposition Process

An electroless deposition process may be performed directly on an unprepared surface, or, more typically, may include an activation process prior to electroless deposition. An activation solution may be applied to a substrate in order to prepare the surface of the substrate as necessary for subsequent electroless deposition. For example, when depositing a metal layer on a silicon surface, the activation process may include a hydrogen fluoride (HF) based wet cleaning process, described below. In another example, the activation process may include the formation of an initiation, or catalytic, layer, also described in detail below.

In a typical activation process, a substrate is transferred into a processing station and rotated at a suitable rpm for evenly distributing an activation solution dispensed thereon, i.e., 50-500 rpm. An activation solution is then dispensed onto the frontside of the substrate. Alternatively, the substrate may be completely immersed in an activation solution so that all surfaces of the substrate are exposed thereto. As another alternative, a substrate may remain stationary during the activation process and a processing fluid is applied to the surface of the substrate with hydrodynamic conditions suitable for the activation process. For example, the processing fluid may be applied via a nozzle array, in a turbulent tank, or by other means. The suitable application time for an activation process varies depending on activation solution concentration and composition, but is generally less than about 2 minutes.

Similarly, in a typical electroless deposition process, a substrate is transferred into deposition station and rotated at a suitable rate of rotation and a deposition solution is dispensed onto the frontside of the substrate. Because of the sensitivity to temperature of the electroless deposition process, the substrate, as well as fluids applied to the substrate surface, may be temperature-controlled. The substrate temperature may be controlled by filling a narrow space between the bottom surface of the substrate and a horizontal platen assembly with a temperature-controlled fluid, which is dispensed onto the platen assembly. Alternatively, the substrate may be immersed in an electroless deposition solution so that all surfaces of the substrate are exposed thereto. Or, as noted above regarding the activation process, processing fluids may be applied to surfaces of a stationary substrate. Duration of exposure to the deposition solution is a function of the composition and temperature of the deposition solution, desired thickness of the deposited layer, and material make-up of the deposited layer, among other factors.

### Ohmic Contact Layer Formation

It is known in the art that the formation of an ohmic contact between a semiconductor and a metal conductor is a sensitive aspect of semiconductor manufacturing. An ohmic contact is defined as a metal-semiconductor contact that has a negligible contact resistance relative to the bulk or series resistance of the semiconductor. A satisfactory ohmic contact should not significantly degrade device performance and can pass the required current with a voltage drop that is small compared with the drop across the active region of the semiconductor device. Even an extremely thin interfacial layer between the semiconductor and the metal, such as a native oxide on the semiconductor, or a chemical reaction between the metal and the semiconductor, may cause such a voltage drop. For the formation of an ohmic contact layer on a silicon substrate, it is typically necessary for the deposition of a metallic layer on the silicon substrate followed by an anneal process in which a metal silicide is formed between the metal and semiconductor. Aspects of the invention contemplate the formation of an ohmic contact between an improved contact structure and a semiconductor substrate wherein an anneal process is not necessary, thereby avoiding the issues associated with the anneal process.

FIG. 4A is a flow chart summarizing a process sequence 400 for depositing a conductive layer onto a silicon substrate to form an improved contact for a solar cell, including the solar cells depicted in FIGS. 3A, 3B, and 3C. Process sequence 400 may be used for the formation of ohmic contact layer 357A, illustrated in FIG. 3C, or activation layer 333A illustrated in FIG. 3D.

In step 401, a solar cell substrate having an exposed silicon surface may undergo a cleaning step to remove native oxide formed on the exposed silicon surface and to properly prepare the surface for the formation of a metal silicide thereon. An “HF last” or a buffered oxide etch (BOE) process may be used. The HF last process is a silicon surface preparation sequence in which HF etching of native oxide is performed on a silicon surface leaving a silicon surface that is hydrogen-terminated (i.e., covered with a silicon-hydride mono-layer). BOE solutions generally contain alkanolamine compounds and an etchant, such as hydrogen fluoride, that also selectively etch native oxides and leave a hydrogen-terminated silicon surface. Both the HF last and BOE processes may be performed in a typical electroless deposition station, as described above. The hydrogen-terminated surface produced by these processes may allow the formation of a suitable ohmic contact layer when a metal-containing layer is deposited thereon. Examples of HF last and BOE cleaning processes that may be used to produce a suitable surface for the subsequent formation of a metal silicide are further described in commonly assigned U.S. patent application Ser. No. 11/385,047, filed Mar. 20, 2006 and in commonly assigned U.S. patent application Ser. No. 11/385,041, filed Mar. 20, 2006, which are both incorporated by reference herein in their entirety.

In step 402, an activation process is performed on the substrate to produce a metal-containing activation layer on the substrate, such as ohmic contact layer 357A illustrated in FIG. 3C or activation layer 333A illustrated in FIG. 3E. In this example, the metal-containing activation layer is a metal silicide-containing material formed on the hydrogen-terminated surface produced by the HF last or BOE process. In one embodiment, the metal-containing activation layer may contain a cobalt material, such as metallic cobalt, cobalt silicide, cobalt phosphide, cobalt boride, cobalt phosphide boride, cobalt tungsten, cobalt tungsten phosphide, cobalt tungsten boride, cobalt tungsten phosphide boride, a cobalt alloy, suicides thereof, or combinations thereof. In another embodiment, the metal-containing activation layer may contain a cobalt nickel material, such as cobalt nickel, cobalt nickel phosphide, cobalt nickel boride, derivatives thereof, alloys thereof, or combinations thereof. In another embodiment, metal-containing activation layer contains a nickel material, such as metallic nickel, nickel silicide, nickel phosphide, nickel boride, nickel phosphide boride, a nickel alloy, or combinations thereof. In other embodiments, the metal-containing activation layer may contain at least one metal, such as cobalt, nickel, tungsten, molybdenum, rhenium, titanium, tantalum, hafnium, zirconium, alloys thereof, or combinations thereof.

In one embodiment of the activation process, a solar cell substrate is exposed to an activation solution containing a cobalt source, a fluoride source, and a hypophosphite source to transform a hydrogen-terminated surface to a metal silicide surface on the solar cell substrate. The metal silicide surface so formed is an activation layer, such as ohmic contact layer 357A illustrated in FIG. 3C or activation layer 333A illustrated in FIG. 3D. Examples of an activation process, including useful cobalt, fluoride, and hypophosphite sources that may be used to produce a suitable surface for the subsequent formation of a metal silicide, are further described in commonly assigned U.S. patent application Ser. No. 11/385,047, filed Mar. 20, 2006.

### Barrier Layer Formation

As noted above, it may be beneficial for a solar cell structure to include an electrolessly deposited barrier layer between the doped silicon regions of the solar cell and the metal-containing contact structure of the solar cell. For example, referring to FIG. 3A, a barrier layer may be advantageously disposed between n-type emitter region 102 and bulk conductive layer 331 to inhibit the diffusion of bulk conductive layer 331 component(s) into n-type emitter region 102.

Referring back to FIG. 3E, barrier layer 333C is formed onto an ohmic contact layer, i.e., activation layer 333A, by a selective electroless deposition process. In general, barrier layer 333C contains one or more layers of material that act as an adhesion layer as well as a diffusion barrier for the subsequently deposited conductive layer 333B. In one aspect, a portion of barrier layer 333C is selected so that it will react with traces of residual oxide on the surface of activation layer 333A to further provide a low resistance connection thereto.

The exposed surface of barrier layer 333C may have a catalytically active surface for the subsequent electroless deposition of conductive layer 333B. For example, in some embodiments, it may be desirable to form barrier layer 333C with an exposed surface layer that contains a group VIII metal, such as ruthenium (Ru), cobalt (Co), nickel (Ni), rhodium (Rh), iridium (Ir), palladium (Pd) or platinum (Pt) to serve as a catalytically active initiation and adhesion layer for the subsequently deposited metal layer, conductive layer 333B.

The barrier layer 1521 may also contain one or more layers that contain titanium (Ti), titanium nitride (TiN), tantalum (Ta), tantalum nitride (TaN), tungsten (W), molybdenum (Mo), tungsten nitride (WN), tungsten carbon nitride (WCN), molybdenum carbon nitride (MoCN), tantalum carbon nitride (TaCN), titanium silicon nitride (TiSiN), or any other combinations thereof. One or more of the layers in the barrier layer may be selectively deposited by use of an electroless deposition process. The electroless deposition process may be used to form a layer that contains a binary alloy or ternary alloy, such as cobalt boride (CoB), cobalt phosphide (CoP), nickel boride (NiB), nickel phosphide (NiP), cobalt tungsten phosphide (CoWP), cobalt tungsten boride (CoWB), nickel tungsten phosphide (NiWP), nickel tungsten boride (NiWB), cobalt molybdenum phosphide (CoMoP), cobalt molybdenum boride (CoMoB), nickel molybdenum phosphide (NiMoB), nickel molybdenum phosphide (NiMoP), nickel rhenium phosphide (NiReP), nickel rhenium boride (NiReB), cobalt rhenium boride (CoReB), cobalt rhenium phosphide (CoReP), derivatives thereof, or combinations thereof. Examples of electroless deposition methods and chemistries for the formation of a barrier layer on the surface of a metal silicide are further described in commonly assigned U.S. patent application Ser. No. 11/385,344, filed Mar. 20, 2006.

Alternatively, conductive layer 333B and barrier layer 333C may be deposited by another method than electroless deposition, such as by PVD, ALD, or CVD, in which case activation layer 333A is formed as an ohmic contact layer by a thermal anneal process.

### Seed Layer/Bulk Conductive Layer Formation

Aspects of the invention contemplate the formation of a seed and/or bulk conductive layer via electroless deposition to form an improved contact structure for a solar cell. In one example, referring back to FIG. 3D, conductive layer 333B may be an electrolessly deposited seed layer formed onto an ohmic contact layer of a solar cell structure, such as activation layer 333A. In another example, bulk conductive layer 331 is a layer of low resistance metal, such as copper, that is electrolessly deposited onto conductive layer 333B, wherein conductive layer 333B is a seed layer deposited by a method other than electroless deposition, e.g., PVD, CVD, or ALD. In yet another example, bulk conductive layer 357B, shown in FIG. 3C, is a conductive layer that is electrolessly deposited on ohmic contact layer 357A. In any of these examples, the process of activation and displacement plating may be used to electrolessly deposit a desired layer of conductive material onto a solar cell structure.

FIG. 4B is a flow chart summarizing a process sequence 420 for selectively depositing a seed and/or bulk conductive layer via electroless deposition onto a previously formed metal-containing layer of a solar cell structure, such as an ohmic contact layer or a PVD-deposited seed layer. Referring to FIG. 3F, which illustrates an enlarged view of the region of a contact indicated in FIG. 3A, process sequence 420 may be used to selectively deposit a conductive layer 362 onto an existing metal-containing layer 361 on the surface of a solar cell structure. Conductive layer 362 may be a seed layer for subsequent electroplating of a bulk conductive layer. Alternatively, conductive layer 362 may serve as the bulk conductive layer of the solar cell contact structure. Metal-containing layer 361 may be an ohmic contact layer on the surface of a solar cell structure or metal-containing layer 361 may be a PVD, CVD, or ALD-deposited seed layer.

Referring to FIGS. 3F and 4B, an activation layer 360 is formed on metal-containing layer 361 in step 421 by exposing metal-containing layer 361 to a suitable activation solution in a standard electroless deposition chamber as described above. Activation layer 360 is a mono-layer thickness initiation layer formed on metal-containing layer 361 by displacement plating of a catalytic metal such a palladium (Pd), platinum (Pt), ruthenium (Ru), osmium (Os), rhodium (Rh), or iridium (Ir). Displacement plating is the replacement or sacrifice of existing atoms on the upper surface of a material, e.g., metal-containing layer 361, by a secondary element, (e.g., palladium, platinum, ruthenium, etc.). Typical procedures for cleaning and displacement plating of a metal-containing layer with palladium employ dilute aqueous acid solutions of palladium salts such as palladium chloride, palladium nitrate or palladium sulfate.

In step 422, an optional rinse process is used to activate activation layer 360 and clean the substrate surface. In this step a rinse activation solution is dispensed on the substrate surface to activate the activation layer formed in step 421.

In step 423, an optional chelating process that uses a chelating solution is dispensed on the substrate surface to clean the substrate surface and/or remove remaining contaminants from any of the early processes. The chelating solution is used to remove and prevent particles from forming on the activated surface.

In step 424, conductive layer 362 is formed on activation layer 360 via an electroless deposition process. Conductive layer 362 may be selectively deposited so that conductive layer 362 is only formed on regions of exposed metal, i.e., activation layer 360. Therefore, conductive layer 362 does not form on all surfaces of the solar cell substrate exposed to the electroless deposition solution.

Conductive layer 362 may contain a conductive metal that includes copper (Cu), tungsten (W), aluminum (Al), ruthenium (Ru), nickel (Ni), cobalt (Co), alloys thereof, derivatives thereof, or combinations thereof, although copper is preferred due to its low resistivity. Conductive layer 362 may also include cobalt boride (CoB), cobalt phosphide (CoP), cobalt tungsten phosphide (CoWP), cobalt tungsten boride (CoWB), cobalt molybdenum phosphide (CoMoP), cobalt molybdenum boride (CoMoB), cobalt rhenium boride (CoReB), cobalt rhenium phosphide (CoReP), nickel boride (NiB), nickel phosphide (NiP), nickel tungsten phosphide (NiWP), nickel tungsten boride (NiWB), nickel molybdenum phosphide (NiMoB), nickel molybdenum phosphide (NiMoP), nickel rhenium phosphide (NiReP), and nickel rhenium boride (NiReB), derivatives thereof or combinations thereof.

Examples of suitable methods and solutions for activation, rinse activation, chelating, and electroless deposition for the formation of a conductive layer on an existing metal-containing layer are described in commonly assigned U.S. patent application Ser. No. 11/385,290, filed Mar. 20, 2006, which is incorporated by reference herein in its entirety.

### Capping Layer Formation

Embodiments of the invention contemplate the selective electroless deposition of a protective layer of conductive material, also referred to as a capping layer, on surfaces of a solar cell contact structure that are susceptible to oxidation. Capping layer 332, depicted in FIG. 3A, and capping layer 357C, depicted in FIG. 3C, are examples of such a capping layer. Surfaces that may benefit from a capping layer are described above in conjunction with FIG. 3A. The capping layer may include a cobalt-containing alloy and/or a tin (Sn) containing alloy layer and is formed using a similar activation and displacement plating method using selective electroless deposition described above in conjunction with FIG. 4B. In addition, a description of chemistries and methods for forming a capping layer on a bulk conductive layer may be found in commonly assigned U.S. patent application Ser. No. 10/970,354, filed Oct. 21, 2004 and in commonly assigned U.S. patent application Ser. No. 10/967,919, filed Oct. 18, 2004.

Examples of cobalt alloys that may be electrolessly deposited as a capping layer include, but are not limited to cobalt boride (CoB), cobalt phosphide (CoP), cobalt tungsten phosphide (CoWP), cobalt tungsten boride (CoWB), cobalt molybdenum phosphide (CoMoP), cobalt molybdenum boride (CoMoB), cobalt rhenium boride (CoReB), cobalt rhenium phosphide (CoReP), derivatives thereof, or combinations thereof. Examples of nickel alloys that may be electrolessly deposited as a capping layer include, but are not limited to nickel boride (NiB), nickel phosphide (NiP), nickel tungsten phosphide (NiWP), nickel tungsten boride (NiWB), nickel molybdenum phosphide (NiMoB), nickel molybdenum phosphide (NiMoP), nickel rhenium phosphide (NiReP), nickel rhenium boride (NiReB), derivatives thereof, or combinations thereof. Examples of tin alloys that may be electrolessly deposited as a capping layer include, but are not limited to, tin (Sn), tin-copper (SnCu), tin-silver (SnAg), and tin-copper-silver (SnCuAg). Tin alloys may also include bismuth (Bi), cobalt (Co), nickel (Ni), antimony (Sb), and zinc (Zn) in their compositions to increase adhesion, reduce tin whisker formation that may cause electrical shunts, and control the melting point of the alloy for robust soldering.

### Contact Structure Formation

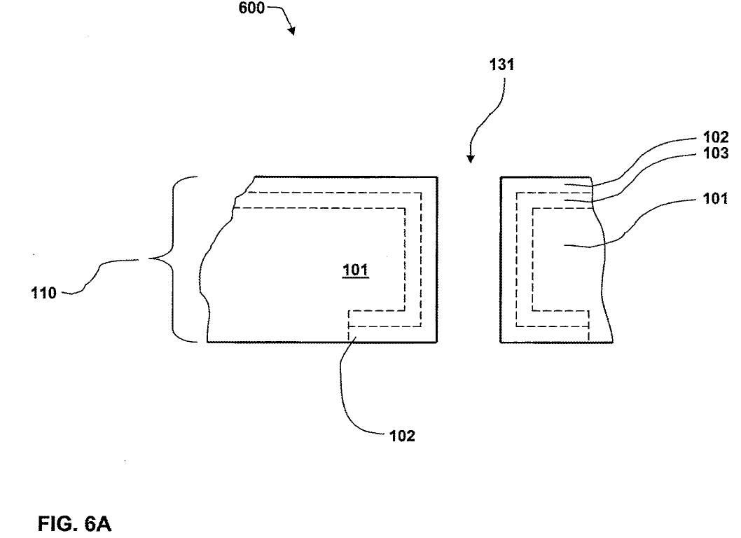

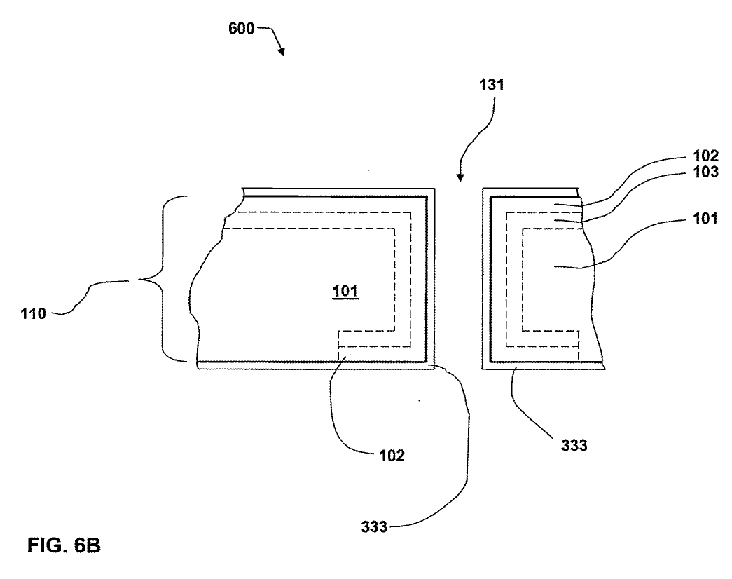

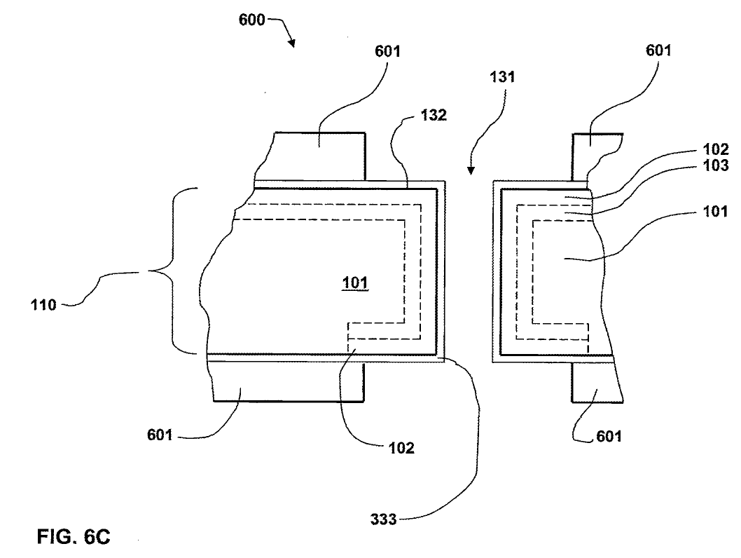

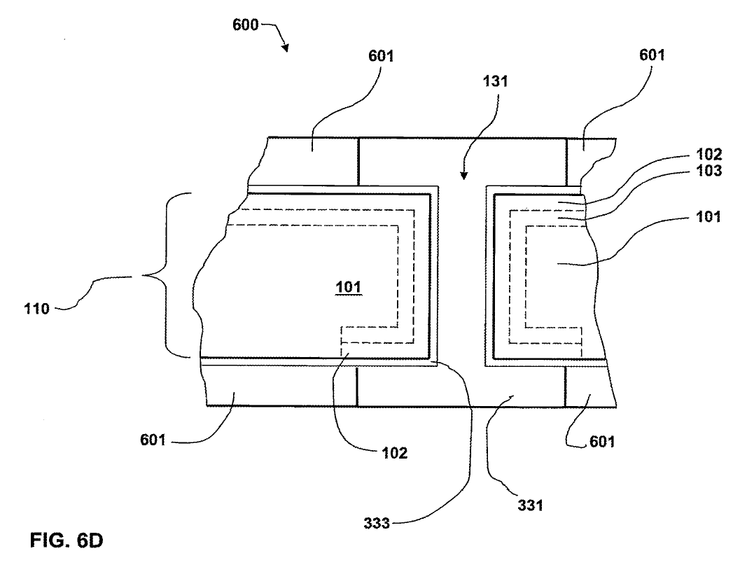

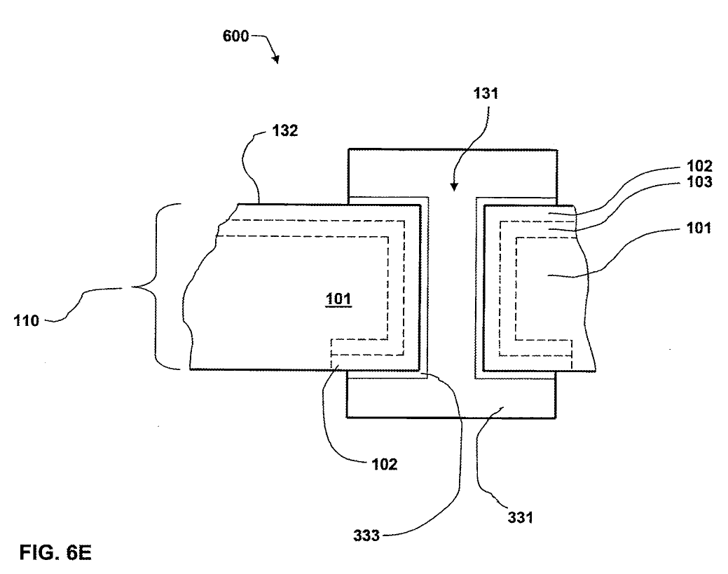

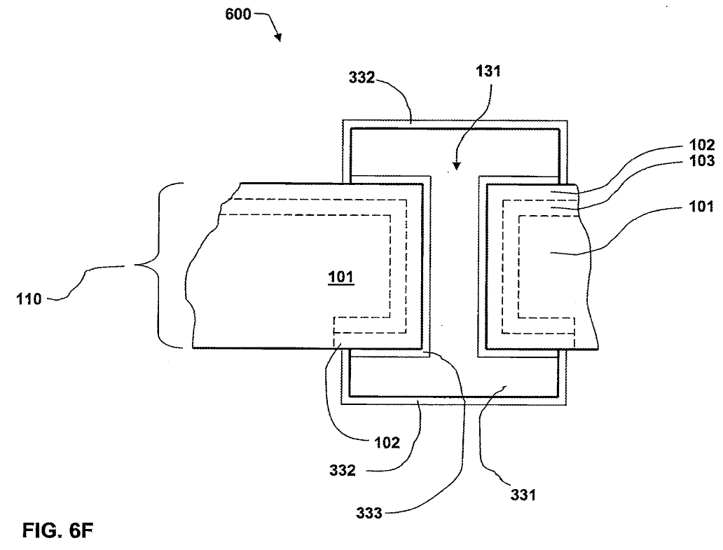

Embodiments of the invention further contemplate methods for the formation of an improved solar cell contact structure using the methods described above for forming an ohmic contact layer, a barrier layer, a seed layer, a bulk conductive layer, and a capping layer. FIG. 5A is a flow chart summarizing a process sequence 500, which is an embodiment for forming a contact structure for a solar cell as depicted in FIGS. 3A and 3D. FIGS. 6A-6F are partial schematic side views of a solar cell contact 600 being formed by process sequence 500.

In step 501, a PUM solar cell substrate, such as wafer 110 illustrated in FIGS. 6A-F, is provided with the desired n-type emitter regions 102 and p-type base regions 101 formed on the substrate by doping and masking techniques commonly used and well known to those skilled in the art of semiconductor fabrication. Through-holes 131, which are required for the formation of contacts, are also formed in the substrate by methods known to those skilled in the art.

In step 502, a seed layer 333, illustrated in FIG. 6B, is deposited by a PVD, CVD, or ALD process, or by electroless deposition. PVD, CVD, and ALD processes result in the non-selective coverage of all exposed surfaces of wafer 110 with seed layer 333. Optionally, a barrier layer may first be deposited on the substrate by a PVD, CV, or ALD process.

In step 503, a plating mask 601 is deposited as illustrated in FIG. 6C using deposition, lithographic patterning, and etching methods known in the art of integrated circuit manufacturing. Alternatively, other lithographic methods may be employed, including screen printing, ink jet printing, stamp printing, and molecular printing, among others. The plating mask precisely defines the geometry of top and bottom contact structures by preventing any deposition of a bulk conductive layer on unwanted portions of light-receiving surface 132. One example of top contact structures that may benefit from being precisely defined is the finger segments 135A of grid electrode 138, depicted in FIG. 1C.

In step 504, a bulk conductive layer 331 is deposited on all exposed metal surfaces of the substrate via electrochemical plating or electroless plating, as illustrated in FIG. 6D. Bulk conductive layer 331 may be any metal-containing material or alloy that can be electrochemically or electrolessly deposited, however copper is generally preferred due to its low conductivity. Methods for bulk conductive layer formation are described above in conjunction with FIG. 4B.

In step 505, the plating mask is removed by etching methods commonly known in the art of semiconductor manufacturing.

In step 506, the exposed portion of seed layer 333 is removed by etching methods commonly known in the art of semiconductor manufacturing, leaving light-receiving surface 132 exposed except where the top contact structure of solar cell contact 600 has been formed. FIG. 6E illustrates solar cell contact 600 after the removal of plating mask 601 and the exposed portion of seed layer 333.

In step 507, a capping layer 332 is selectively deposited on all exposed metallic surfaces present on solar cell contact 600 as illustrated in FIG. 6F. The method used for capping layer formation is described above in conjunction with FIG. 4B.

Alternatively, capping layer 332 may be deposited by selective electroless deposition onto bulk conductive layer 331 in step 504, prior to the removal of the plating mask. In this aspect, capping layer 332 is only formed on the bottom and top surfaces of bulk conductive layer 331 and not on the exposed sidewalls of capping layer 332.

In another embodiment, an improved solar cell contact structure may be formed using an electrolessly deposited seed layer. FIG. 5B is a flow chart summarizing a process sequence 520 for forming a contact structure for a solar cell with an electroless seed layer.

In step 521, a PUM solar cell substrate is provided as described in step 501, above.

In step 522, a plating mask is formed over the regions of the light-receiving surface to define the geometry of the contact structure thereon, i.e., the grid electrode. This procedure is described above in step 503 of process sequence 500.

In step 523, an ohmic contact layer is formed on all exposed surfaces of the solar cell substrate using the methods described above in conjunction with FIG. 4A.

In step 524, a seed layer is deposited via a selective electroless process onto the ohmic contact layer as described above in conjunction with FIG. 4B. Optionally, a barrier layer may first be formed on the ohmic contact layer via a selective electroless deposition method as described above.

In step 525, a bulk conductive layer is deposited on all exposed metal surfaces, i.e., the electroless seed layer, via electroless deposition. This procedure is described above in conjunction with FIG. 4B.

In step 526, the plating mask is removed, revealing a contact structure and exposed light-receiving surface substantially similar to that illustrated in FIG. 6E.

In step 527, a capping layer is selectively deposited on all exposed metallic surfaces present on the solar cell contact, forming a completed contact structure substantially similar to solar cell contact 600, illustrated in FIG. 6F.

In another embodiment, an improved solar cell contact structure as depicted in FIG. 3E may be formed using sequential electroless deposition steps. FIG. 5C is a flow chart summarizing a process sequence 530 for forming such a contact structure.

In step 531, a PUM solar cell substrate is provided having the desired n-type emitter regions and p-type base regions formed on the substrate by doping and masking techniques commonly used and well known to those skilled in the art of semiconductor fabrication. In addition, the light-receiving surface of the substrate has an anti-reflective coating with apertures therethrough, as illustrated in FIG. 3E. The anti-reflective coating and associated apertures may be formed on the substrate via deposition and masking techniques commonly used in the art of integrated circuit manufacturing.

In step 532, an ohmic contact layer is formed in the apertures of the anti-reflective coating by a selective electroless deposition process as described above in conjunction with FIG. 4A.

In step 533, a bulk conductive layer is formed on the ohmic contact layer using methods described above in conjunction with FIG. 4B. Optionally, a barrier layer may first be formed on the ohmic contact layer by an electroless deposition process using methods described above.

In step 534, a capping layer is selectively deposited on all exposed metallic surfaces present on the solar cell contact, i.e., the bulk conductive layer deposited in step 533. A complete contact structure is formed substantially similar to contact structure 350, illustrated in FIG. 3E.

In step 535, an optional thermal anneal step may be performed to produce more benefical alloy combinations in the contact structure. For example, when the ohmic contact layer as deposited consists of nickel phosphide (NiP), the bulk conductive layer as deposited consists of copper, and the capping layer as deposited consists of tin, a thermal anneal process may form the following alloy system for the ohmic contact layer, bulk conductive layer, and capping layer respectively: (NiPSi—NiP)/(NiPCu—Cu—CuSn)/(Sn).

While the foregoing is directed to embodiments of the present invention, other and further embodiments of the invention may be devised without departing from the basic scope thereof, and the scope thereof is determined by the claims that follow.

What is claimed is:

1. A metal contact structure for a solar cell comprising:
a solar cell substrate having a base region and an emitter region;
a contact disposed adjacent to the emitter region, the contact having a bulk conductive layer and a capping layer that covers the bulk conductive layer.

2. The contact structure of claim 1, wherein the capping layer comprises a material selected from the group consisting of cobalt boride (CoB), cobalt phosphide (CoP), cobalt tungsten phosphide (CoWP), cobalt tungsten boride (CoWB), cobalt molybdenum phosphide (CoMoP), cobalt molybdenum boride (CoMoB), cobalt rhenium boride (CoReB), cobalt rhenium phosphide (CoReP), nickel boride (NiB), nickel phosphide (NiP), nickel tungsten phosphide (NiWP), nickel tungsten boride (NiWB), nickel molybdenum phosphide (NiMoB), nickel molybdenum phosphide (NiMoP), nickel rhenium phosphide (NiReP), nickel rhenium boride (NiReB), tin (Sn), tin-copper (SnCu), tin-silver (SnAg), tin-copper-silver (SnCuAg), bismuth (Bi), cobalt (Co), nickel (Ni), antimony (Sb), and zinc (Zn).

3. The contact structure of claim 1, wherein the contact is disposed within a hole that is formed through the substrate.

4. The contact structure of claim 3, wherein the contact further comprises a seed layer disposed between the bulk conductive layer and the emitter region.

5. The contact structure of claim 4, wherein the seed layer comprises electrolessly deposited copper (Cu).

6. The contact structure of claim 3, wherein the contact further comprises a barrier layer disposed between the bulk conductive layer and the emitter region.

7. The contact structure of claim 6, wherein the barrier layer contains an element selected from a group consisting of titanium (Ti), cobalt (Co), nickel (Ni), tungsten (W), molybdenum (Mo), and tantalum (Ta), and wherein the element is electrolessly deposited.

8. The contact structure of claim 1, wherein the emitter region includes a heavily doped emitter region and a lightly doped emitter region, and an ohmic contact layer is disposed between the bulk conductive layer and the heavily doped emitter region.

9. The contact structure of claim 8, wherein the ohmic contact layer comprises a material selected from the group consisting of nickel (Ni), nickel phosphide (NiP), nickel boride (NiB), cobalt (Co), cobalt tungsten (CoW), cobalt tungsten phosphide (CoWP), cobalt tungsten boride (CoWB), cobalt tungsten phosphide boride (CoWPB), cobalt nickel (CoNi), cobalt phosphide (CoP), cobalt boride (CoB), cobalt nickel phosphide (CoNiP), cobalt nickel boride (CoNiB), palladium (Pd), derivatives thereof, alloys thereof, and combinations thereof.

10. The contact structure of claim 1, wherein the bulk conductive layer comprises electroplated copper (Cu), silver (Ag), or a combination thereof.

11. The contact structure of claim 1, wherein the bulk conductive layer comprises electrolessly plated copper (Cu), silver (Ag), or a combination thereof.

12. The contact structure of claim 1, wherein the solar cell substrate further comprises a light-receiving surface and a non-light-receiving surface and the contact is disposed on the non-light-receiving surface.

13. A metal contact structure for a solar cell comprising:
a solar cell substrate having a base region and an emitter region;
a contact disposed adjacent to the emitter region, the contact having a bulk conductive layer and an electrolessly deposited seed layer disposed between the bulk conductive layer and the emitter region.

14. The contact structure of claim 13, wherein the contact further comprises a capping layer that covers the bulk conductive layer.

15. The contact structure of claim 13, wherein the seed layer comprises an activation layer for electroless deposition.

16. The contact structure of claim 15, wherein the activation layer comprises a material selected from the group consisting of nickel (Ni), nickel phosphide (NiP), nickel boride (NiB), cobalt (Co), cobalt tungsten (CoW), cobalt tungsten phosphide (CoWP), cobalt tungsten boride (CoWB), cobalt tungsten phosphide boride (CoWPB), cobalt nickel (CoNi), cobalt phosphide (CoP), cobalt boride (CoB), cobalt nickel phosphide (CoNiP), cobalt nickel boride (CoNiB), palladium (Pd), derivatives thereof, alloys thereof, and combinations thereof.

17. A method for forming a contact on a solar cell substrate, comprising:
providing a solar cell substrate having an emitter region; and
forming a contact having a bulk conductive layer adjacent the emitter region; and
forming a capping layer on the bulk conductive layer through an electroless plating process.

18. The method of claim 17, wherein the step of forming the contact comprises forming an activation layer adjacent the emitter region, and wherein the bulk conductive layer is formed on the activation layer through an electroless plating process.

19. The method of claim 18, wherein the step of forming the contact further comprises forming a barrier layer on the activation layer, and wherein the bulk conductive layer is formed on the barrier layer.

20. The method of claim 17, wherein the step of forming the contact further comprises forming a seed layer adjacent the emitter region through a PVD process and forming an activation layer on the seed layer, and wherein the bulk conductive layer is formed on the barrier layer.

21. The method of claim 17, wherein the step of forming the contact further comprises forming an ohmic contact layer adjacent the emitter region, and wherein the bulk conductive layer is formed on the ohmic contact layer.

22. A method for forming a contact on a solar cell substrate, comprising:
providing a solar cell substrate;
forming an activation layer for electroless deposition; and
forming a bulk conductive layer for the contact on the activation layer.

23. The method of claim 22, further comprising: forming a capping layer to cover the bulk conductive layer.

24. The method of claim 23, further comprising: forming a barrier layer in between the activation layer and the bulk conductive layer.

25. The method of claim 22, wherein the substrate has a through-hole and the activation layer is formed on the sidewalls of the through-hole.

26. The method of claim 25, wherein the process of forming a bulk conductive layer on the activation layer comprises:
forming a seed layer on the activation layer through an electroless plating process; and
forming a conductive layer on the seed layer though an electrochemical plating process.

27. The method of claim 25, wherein the process of forming a bulk conductive layer comprises forming a conductive layer on the activation layer through an electroless plating process.

28. The method of claim 22, wherein the process of forming a bulk conductive layer on the activation layer is an electroless plating process.
